(19) United States
(12) Patent Application Publication
(10) Pub. No.: US 2014/0027161 A1
(43) Pub. Date: Jan. 30, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventor: Kiwon Lee, Suwon (KR)

(73) Assignee: SAMSUNG ELECTRO-MECHANICS CO., LTD., Suwon (KR)

(21) Appl. No.: 13/677,076

(22) Filed: Nov. 14, 2012

(30) Foreign Application Priority Data
Jul. 24, 2012 (KR) 10-2012-0080655

(51) Int. Cl. H05K 1/09; H05K 1/02

(52) U.S. Cl. CPC H05K 1/09; H05K 1/0213; B82Y 30/00
USPC 174/257; 174/250; 216/13; 977/734

(57) ABSTRACT

Disclosed herein is a printed circuit board including: a substrate; one or more elastic electrode formed on the substrate and made of an elastic material; and one or more metal electrode formed on the elastic electrode.

### CROSS REFERENCE TO RELATED APPLICATION

This application claims the benefit of Korean Patent Application No. 10-2012-0080655, filed on Jul. 24, 2012, entitled “Printed Circuit Board and Method for Manufacturing of Printed Circuit Board”, which is hereby incorporated by reference in its entirety into this application.

### BACKGROUND OF THE INVENTION

1. Technical Field The present invention relates to a printed circuit board and a method for manufacturing the same.

2. Description of the Related Art

A printed circuit board is a board that electrically connects a plurality of components to an electrical or electronic device to enable the components electrically connected to each other to exchange power or electrical signals with each other. The printed circuit board has been widely used throughout electrical and electronic devices, such as mobile phones, laptop computers, display devices, or the like.

The printed circuit board may be divided into a rigid substrate, a flexible substrate, or a rigid and flexible substrate. Here, the flexible substrate may be bent.

At the time of forming the printed circuit board, the printed circuit board is subjected to various high temperature processes, such that a deformation such as warpage, or the like, may be generated in the printed circuit board. In addition, the flexible substrate may be mounted with the electronics components in the state in which it is bent. In this case, in order to electrically connect the printed circuit board to an external electronic component, an electrode may be formed on the printed circuit board. In general, the electrode may be formed on the printed circuit board in a length or width direction (U.S. Pat. No. 7,593,085). As described above, in the case in which the printed circuit board is excessively deformed, damage such as disconnection, or the like, of the electrodes formed on the printed circuit board may be generated.

### SUMMARY OF THE INVENTION

The present invention has been made in an effort to provide a printed circuit board having high durability against a deformation thereof; and a method for manufacturing the same.

Further, the present invention has been made in an effort to provide a printed circuit board having improved reliability, and a method for manufacturing the same.

Further, the present invention has been made in an effort to provide a printed circuit board capable of being implemented in a micro thin thickness, and a method for manufacturing the same.

According to a preferred embodiment of the present invention, there is provided a printed circuit board including: a substrate; one or more elastic electrode formed on the substrate and made of an elastic material; and one or more metal electrode formed on the elastic electrode.

The elastic electrode may be made of graphene or graphene oxide.

The metal electrode may be made of a conductive metal.

The printed circuit board may further include a seed layer formed between the metal electrode and the elastic electrode.

The metal electrodes may be formed on both sides of the elastic electrodes.

According to another preferred embodiment of the present invention, there is provided a method for manufacturing a printed circuit board, the method including: preparing a carrier member having metal layers formed over the entire upper surface thereof; primarily patterning the metal layers; forming elastic metal layers on the primarily patterned metal layers and the carrier member; forming a substrate on the elastic metal layers; forming elastic electrodes by removing the carrier member; and forming metal electrodes by secondarily patterning the primarily patterned metal layer.

The forming of the primarily patterned metal layers may be performed by patterning the metal layers in a form corresponding to the elastic electrodes.

In the forming of the metal electrodes, the secondary patterning may be performed on the primarily patterned metal layers so that one or more metal electrodes are formed on the elastic electrodes.

In the forming of the metal electrodes, the secondary patterning may be performed on the primarily patterned metal layers so that the metal electrodes are formed on both sides of the elastic electrodes.

The metal electrodes may be made of a conductive metal.

In the forming of the elastic metal layers, the elastic metal layers may be formed by an oxidation and reduction method.

The elastic metal layers may be made of graphene or graphene oxide.

According to another preferred embodiment of the present invention, there is provided a method for manufacturing a printed circuit board, the method including: preparing a carrier member having metal layers formed over the entire upper surface thereof; primarily patterning the metal layers; forming elastic electrodes on the primarily patterned metal layers; forming a substrate on the elastic electrodes; removing the carrier member; and forming metal electrodes by secondarily patterning the primarily patterned metal layers.

The forming of the primarily patterned metal layers may be performed by patterning the metal layers in a form corresponding to the elastic electrodes

In the forming of the elastic electrodes, the elastic electrodes may be formed by a chemical vapor deposition (CVD).

The method may further include, after the forming of the primarily patterned metal layers, forming seed layers on the primarily patterned metal layers.

In the forming of the metal electrodes, the secondary patterning may be performed on the primarily patterned metal layers so that one or more metal layers are formed on the elastic electrodes.

In the forming of the metal electrodes, the secondary patterning may be performed on the primarily patterned metal layers so that the metal electrodes are formed on both sides of the elastic electrodes.

The metal electrodes may be made of a conductive metal.

The elastic metal layer may be made of graphene or graphene oxide.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a printed circuit board according to a preferred embodiment of the present invention;

FIGS. 2 to 7 are views showing a method for manufacturing a printed circuit board according to a preferred embodiment of the present invention; and

FIGS. 8 to 14 are views showing a method for manufacturing a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

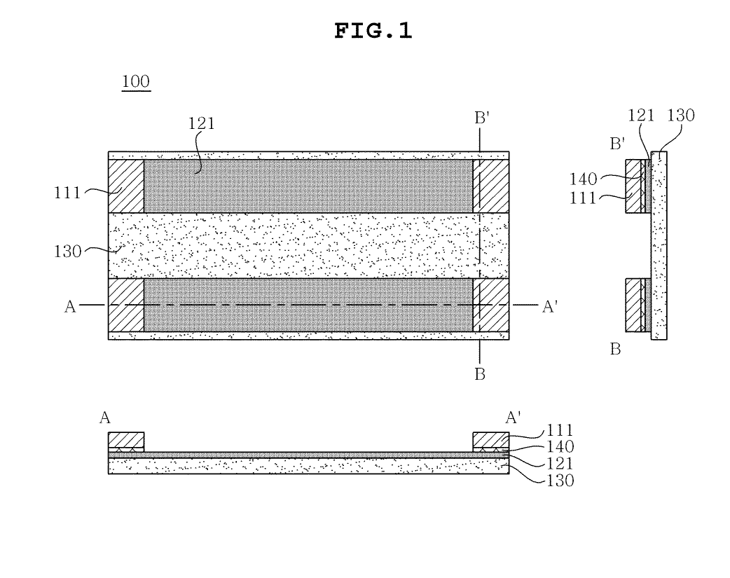

FIG. 1 is a view showing a printed circuit board according to a preferred embodiment of the present invention.

Referring to FIG. 1, a printed circuit board 100 may be configured to include a substrate 130, an elastic electrode 121, a metal electrode 111, and a seed layer 140.

In order to assist in understanding the present invention, a plan view of the printed circuit board 100 according to the preferred embodiment of the present invention, and a front view (A-A′) and a side view of the printed circuit board 100 based on the plan view are shown in FIG. 1, respectively.

The substrate 130 may be at least one of a flexible substrate, a rigid substrate, and a rigid and flexible substrate. For example, in the case in which the substrate 130 is the flexible substrate, the substrate 130 may be formed of a polymer film, such as a poly imide (PT) film, a polyethyleneterephthalate (PET) film, or the like.

The elastic electrode 121 may be formed on the substrate 130. The elastic electrode 121 may be made of graphene or graphene oxide. The graphene may be made of carbon atoms and be a thin film having a thickness of one carbon atom. The graphene may have electric conductivity about 100 times or more higher than that of copper. In addition, the graphene may be a substance capable of moving an electron at a speed about 100 times or more faster than that of single crystal silicon mainly used in a semiconductor. In addition, the graphene may have strength 200 times or more stronger than that of steel and have thermal conductivity two times or more higher than that of diamond. In addition, the graphene may be a substance that has excellent elasticity to maintain an electric property thereof even in the case of being strained or bent.

The metal electrode 111 may be formed on the elastic electrode 121. For example, the metal electrodes 111 may be formed on both sides of the elastic electrode 121. The metal electrodes 111 may be formed on a region in which occurrence of deformation of the substrate 130 is less. In the case in which the substrate 130 is bent, the largest deformation is generated at a central region of the substrate 130 and less deformation is generated at regions of both sides thereof as compared to the central region. Therefore, the metal electrodes 111 may be formed on both sides of the elastic electrode 121 formed on the substrate 130. The metal electrode 111 may be made of a conductive metal.

The seed layer 140 may be formed between the elastic electrode 121 and the metal electrode 111. The seed layer 140 may serve as a lead line when the elastic electrode 121 is formed. The seed layer 140 may be made of a conductive metal. For example, the seed layer 140 may be made of the same conductive metal as that of the metal electrode 111. Although the preferred embodiment of the present invention shows the case in which the printed circuit board 100 includes the seed layer 140, the present invention is not limited thereto. That is, the metal electrode 111 serves as the lead line for forming the elastic electrode 121, such that the seed layer 140 may be omitted.

According to the preferred embodiment of the present invention, the metal electrodes 111 may be formed on both sides of the substrate 130 so as to be spaced apart from each other. The metal electrodes 111 formed so as to be spaced apart from each other as described above may be electrically connected to each other by the elastic electrode 121. Since the elastic electrode 121 is made of the graphene to have excellent elasticity, even though deformation is generated in the substrate 130, the possibility that a defect such as electrode disconnection, or the like will be generated is low. That is, according to the preferred embodiment of the present invention, the metal electrodes 111 are formed on both sides of the substrate 130 in which the deformation is hardly generated and are connected to each other by the elastic electrode 121 having the high elasticity, thereby making it possible to improve durability and reliability of the printed circuit board 100.

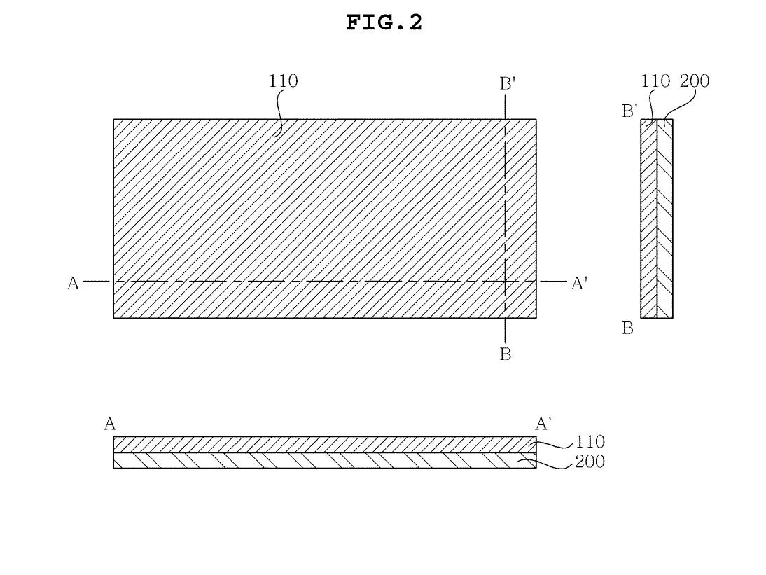

FIGS. 2 to 7 are views showing a method for manufacturing a printed circuit board according to a preferred embodiment of the present invention.

In order to assist in understanding the method for manufacturing a printed circuit board according the preferred embodiment of the present invention, a plan view of the printed circuit board, and a front view (A-A′) and a side view (B-B′) of the printed circuit board based on the plan view are shown in FIGS. 2 to 7, respectively.

Referring to FIG. 2, a carrier member 200 having a metal layer 110 formed thereon may be provided. Here, the metal layer 110 may be formed over the entire upper surface of the carrier member 200. According to the preferred embodiment of the present invention, the carrier member 200 may have a film form such as a metal foil, a polymer film, or the like.

The metal layer 110 may be later patterned to become a metal electrode 111. The metal layer 110 may be made of a conductive metal.

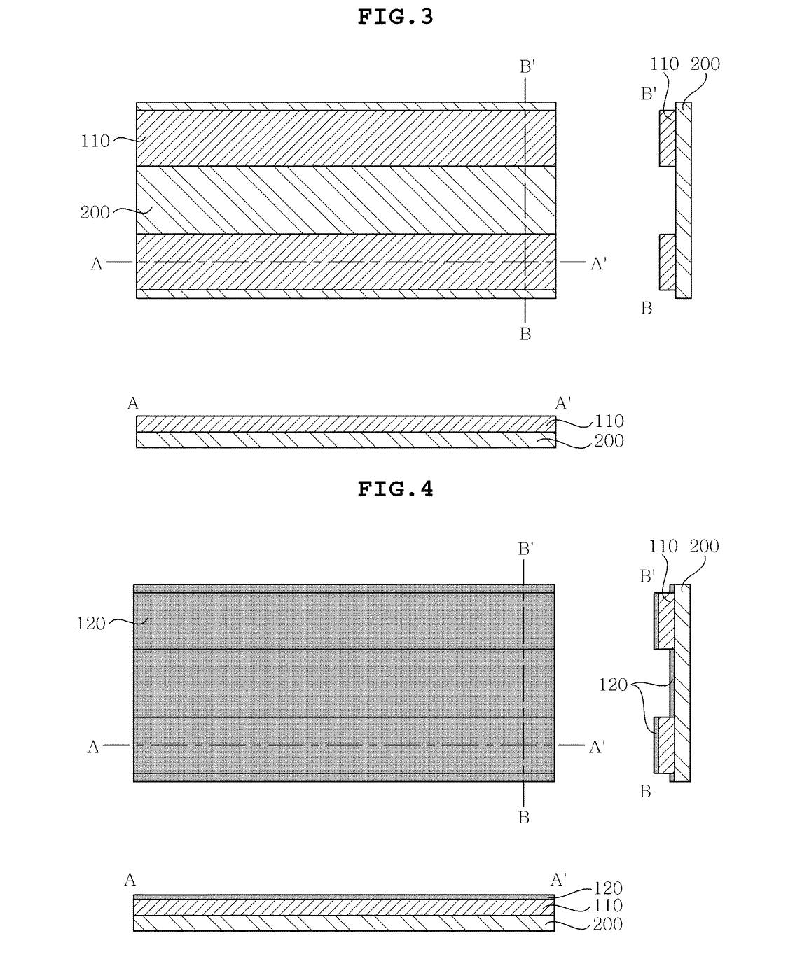

Referring to FIG. 3, the metal layer 110 may be primarily patterned. The primary patterning may be performed so that the metal layer 110 remains only on a portion on which the metal electrode 111 is to be formed. That is, remaining regions of the metal layer 100 except for the region on which the metal electrode 111 is to be formed may be etched. Here, the primary patterning may be performed using any one of general etching methods such as wet etching, dry etching such as reactive ion etching (RIE), and the like.

Referring to FIG. 4, an elastic metal layer 120 may be formed. The elastic metal layer 120 may be formed on the primarily patterned metal layer 100 and the carrier member 200 exposed by the patterning of the metal layer 110. The elastic metal layer 120 may be made of graphene or graphene oxide. The graphene may be made of carbon atoms and be a thin film having a thickness of one carbon atom. The graphene may have electric conductivity of about 100 times or more higher than that of copper. In addition, the graphene may be a substance capable of moving an electron at a speed about 100 times or more faster than that of a single crystal silicon mainly used in a semiconductor. In addition, the graphene may have strength 200 times or more stronger than that of steel and have thermal conductivity two times or more higher than that of diamond. In addition, the graphene may be a substance that has excellent elasticity to maintain electric property thereof even in the case of being strained or bent.

The elastic metal layer 120 may be formed using a reduction method. In addition, an elastic electrode 121 may be formed using a well-known non-selective forming method as well as the reduction method.

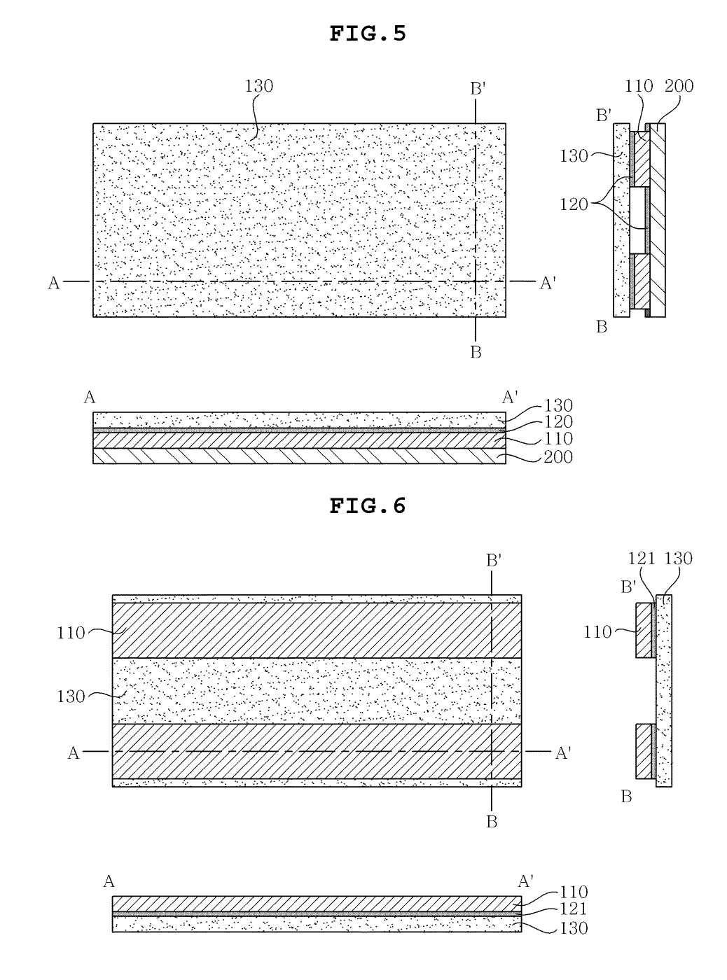

Referring to FIG. 5, a substrate 130 may be formed on the elastic metal layer 120. The substrate 130 may be at least one of a flexible substrate, a rigid substrate, and a rigid and flexible substrate. For example, in the case in which the substrate 130 is the flexible substrate, the substrate 130 may be formed of a polymer film such as a poly imide (P1) film, a poly ethylene terephthalate (PET) film, or the like. The substrate 130 may be formed on the elastic electrode 121 by a method such as a spray coating method, a lamination method, or the like.

Referring to FIG. 6, the carrier member 200 may be removed. Since the carrier member 200 is attached in a film form to the metal layer 100, it may be easily removed from the primarily patterned metal layer 110. When the carrier member 200 is removed, the elastic metal layer 120 formed on the carrier member 200 may also simultaneously removed. Here, as the carrier member 200 is removed, the elastic metal layer 120 may be patterned so as to remain only on the primarily patterned metal layer 110. That is, the elastic metal layer 120 may be patterned in a form of the elastic electrode 121.

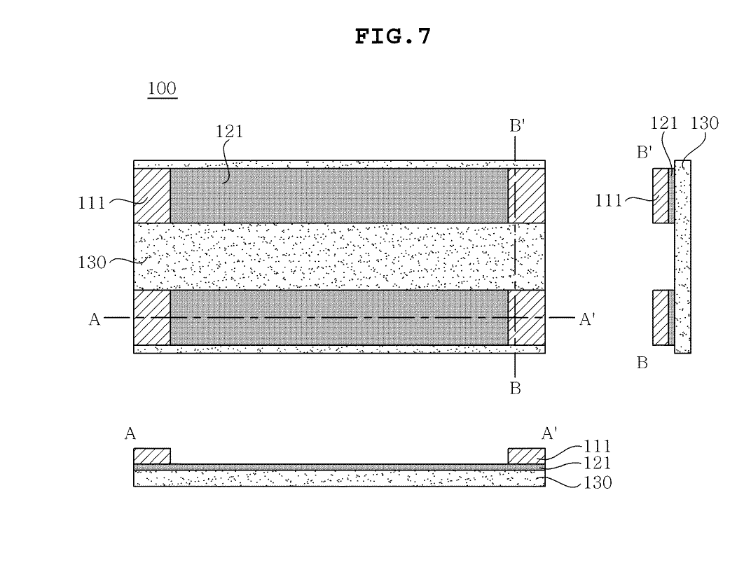

Referring to FIG. 7, one or more metal electrodes 111 may be formed. As the carrier member 200 is removed, the primarily patterned metal layer 110 may be exposed to the outside. The exposed primarily patterned metal layer 110 may be secondarily patterned to form the metal electrode 111. By the secondary patterning, one or more metal electrodes 111 may be formed on the elastic electrodes 121. Here, according to the preferred embodiment of the present invention, the metal electrodes 111 may be formed on both sides of the elastic electrodes 121 corresponding to positions at which deformation is hardly generated, by the secondary patterning. The secondary patterning may be performed using any one of wet etching, dry etching such as reactive ion etching (RIE), and the like.

That is, according to the preferred embodiment of the present invention, the printed circuit board 100 including the metal electrodes 111 formed on both sides of the substrate 130 and the elastic electrode 121 electrically connecting the metal electrodes 111 to each other may be formed.

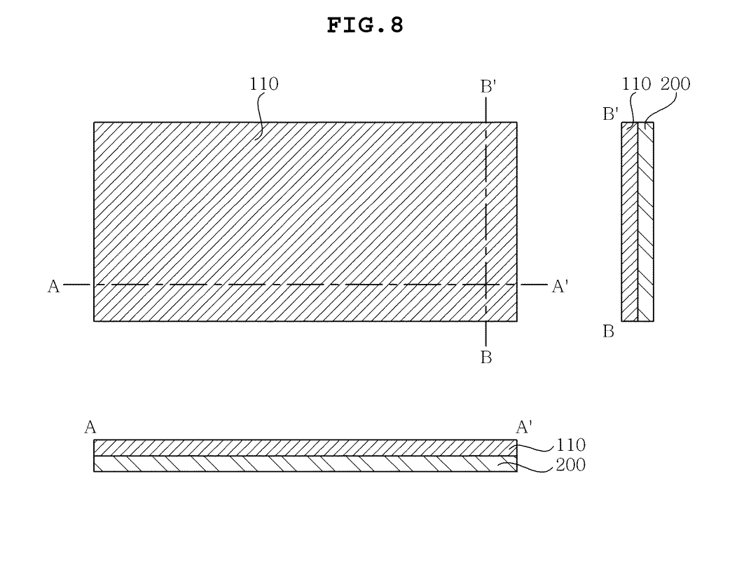

FIGS. 8 to 14 are views showing a method for manufacturing a printed circuit board according to another preferred embodiment of the present invention.

In order to assist in understanding the method for manufacturing the printed circuit board according to another preferred embodiment of the present invention, a plan view of the printed circuit board, and a front view (A-A′) and a side view (B-B′) of the printed circuit board based on the plan view are shown in FIGS. 8 to 14, respectively.

Referring to FIG. 8, a carrier member 200 having a metal layer 110 formed thereon may be provided. Here, the metal layer 110 may be formed over the entire upper surface of the carrier member 200. According to the preferred embodiment of the present invention, the carrier member 200 may have a film form such as a metal foil, a polymer film, or the like.

The metal layer 110 may be then patterned and become a metal electrode 111. The metal layer 110 may be made of a conductive metal.

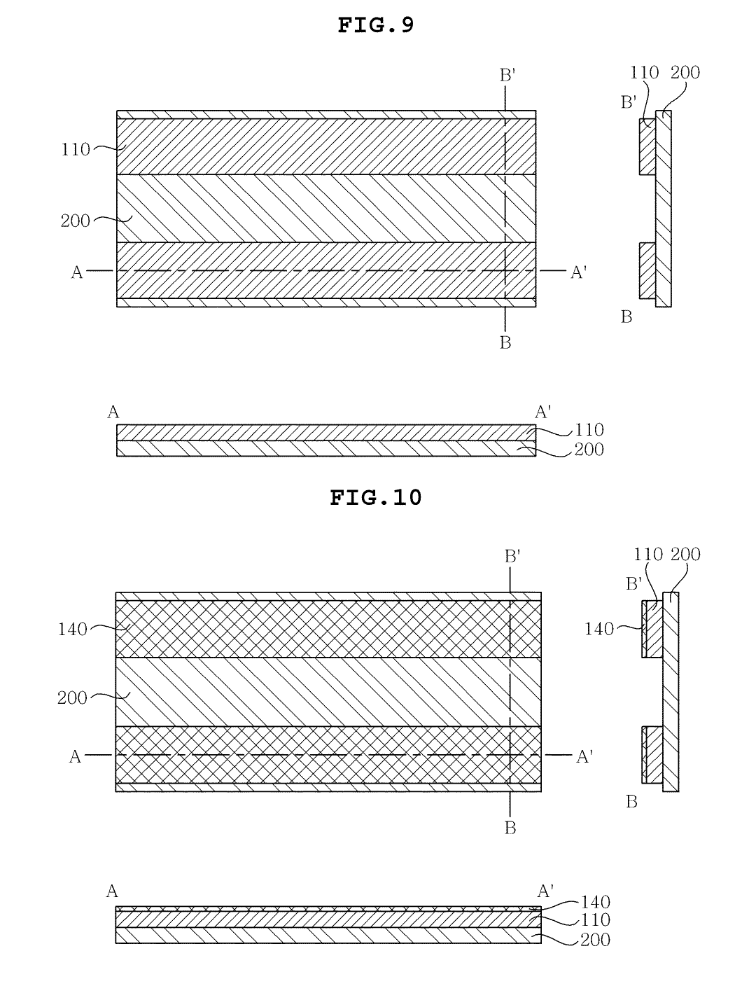

Referring to FIG. 9, the metal layer 110 may be primarily patterned. The primary patterning may be performed so that the metal layer 110 remains only on a portion on which the metal electrode 111 is to be formed. That is, remaining regions of the metal layer 100 except for the region on which the metal electrode 111 is to be formed may be etched. Here, the primary patterning may be performed using any one of general etching methods such as wet etching, dry etching such as reactive ion etching (RIE), and the like.

Referring to FIG. 10, seed layers 140 may be formed. The seed layers 140 may be formed on the primarily patterned metal layers 110. The seed layer 140 may be formed by an electroless plating method. The seed layer 140 may be made of a conductive metal. For example, the seed layer 140 may be made of the same metal as that of the metal layer 110.

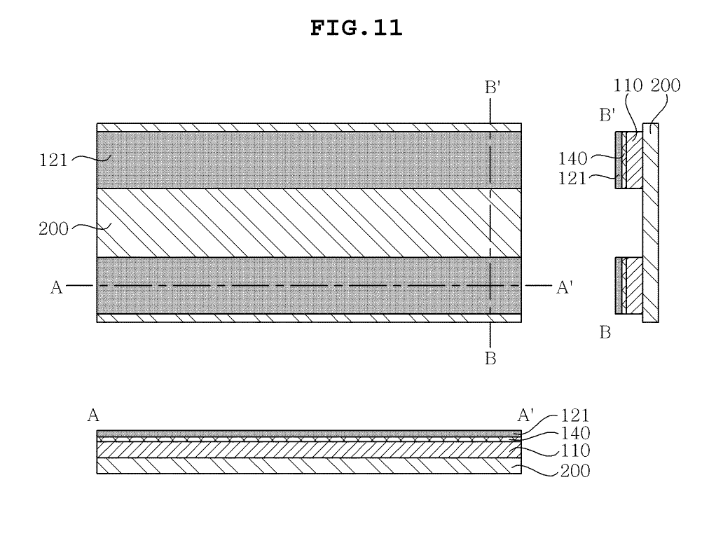

Referring to FIG. 11, elastic electrodes 121 may be formed. The elastic electrode 121 may be formed on the seed layer 140. The elastic electrode 121 may be made of graphene or graphene oxide. The graphene may be made of carbon atoms and be a thin film having a thickness of one carbon atom. The graphene may have electric conductivity about 100 times or more higher than that of copper. In addition, the graphene may be a substance capable of moving an electron at a speed about 100 times or more faster than that of single crystal silicon mainly used in a semiconductor. In addition, the graphene may have strength 200 times or more stronger than that of steel and have thermal conductivity two times or more higher than that of diamond. In addition, the graphene may be a substance that has excellent elasticity to maintain electric property thereof even in the case of being strained or bent.

The elastic electrode 121 may be formed by a chemical vapor deposition (CVD) method. The elastic electrode 121 may be formed using any method in which it may be selectively formed, such as the CVD method. Although the preferred embodiment of the present invention shows the case in which the elastic electrode 121 is formed on the seed layer 140 by way of example, the present invention is not limited thereto. The elastic electrode 121 may be formed on the primarily patterned metal layer 110 using the primarily patterned metal layer 110 as the seed layer. That is, the process of forming the seed layer 140 may be omitted before forming the elastic electrode 121.

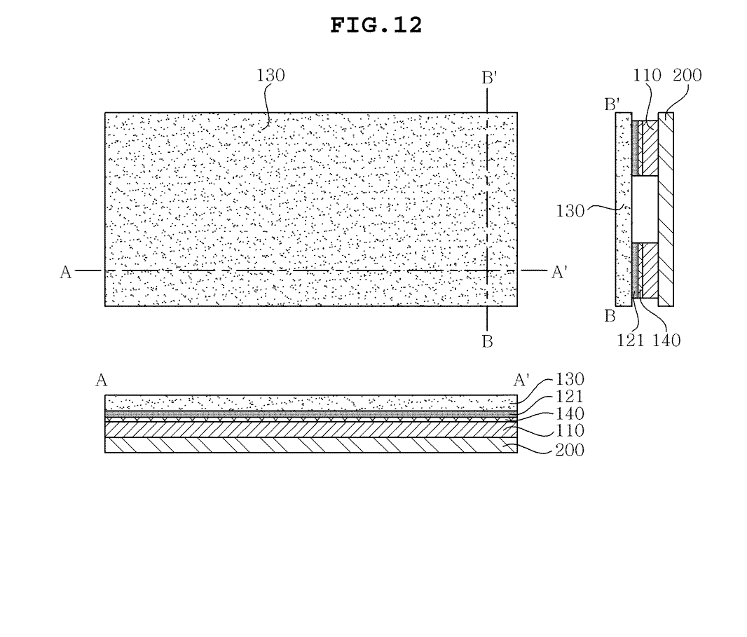

Referring to FIG. 12, a substrate 130 may be formed on the elastic electrode 121. The substrate 130 may be at least one of a flexible substrate, a rigid substrate, and a rigid and flexible substrate. For example, in the case in which the substrate 130 is the flexible substrate, the substrate 130 may be formed of a polymer film such as a poly imide (P1) film, a polyethyleneterephthalate (PET) film, or the like. The substrate 130 may be formed on the elastic electrode 121 by a method such as a spray coating method, a lamination method, or the like.

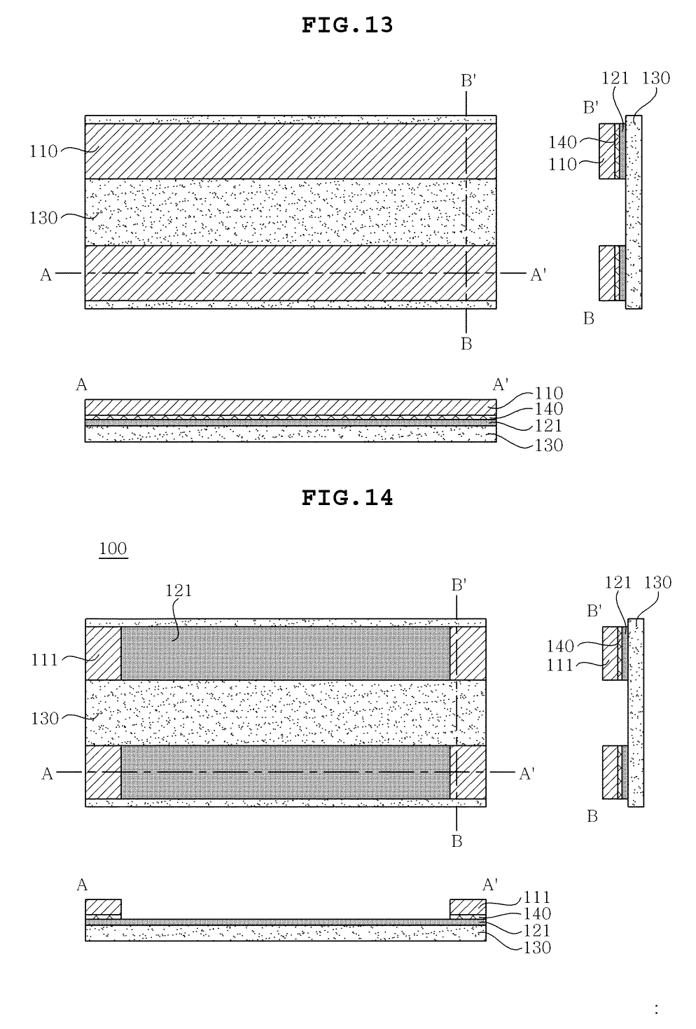

Referring to FIG. 13, the carrier member 200 may be removed. Since the carrier member 200 is attached in a film form to the metal layer 100, it may be easily removed from the primarily patterned metal layer 110.

Referring to FIG. 14, one or more metal electrodes 111 may be formed. AS the carrier member 200 is removed, the primarily patterned metal layer 110 may be exposed to the outside. The exposed primarily metal layer 110 may be secondarily patterned to form the metal electrode 111. By the secondary patterning, one or more metal electrodes 111 may be formed on the elastic electrodes 121. Here, according to the preferred embodiment of the present invention, the metal electrodes 111 may be formed on both sides of the elastic electrodes 121 corresponding to positions at which deformation is hardly generated, by the secondary patterning. The secondary patterning may be performed using any one of general etching methods such as wet etching, dry etching such as reactive ion etching (RIE), and the like.

That is, according to the preferred embodiment of the present invention, the printed circuit board 100 including the metal electrodes 111 formed on both sides of the substrate 130 and the elastic electrode 121 electrically connecting the metal electrodes 111 to each other may be formed.

With the printed circuit board and the method for manufacturing the same according to the preferred embodiments of the present invention, the metal electrodes are formed on both sides of the substrate and the metal electrodes formed on both sides of the substrate are connected to each other by the elastic electrodes made of the graphene, thereby making it possible to provide the printed circuit board having high durability against the deformation thereof.

With the printed circuit board and the method for manufacturing the same according to the preferred embodiments of the present invention, the elastic electrodes are made of the grapheme, thereby making it possible to improve the durability and the reliability of the printed circuit board.

With the printed circuit board and the method for manufacturing the same according to the preferred embodiments of the present invention, the elastic electrode has a very thin thickness, thereby making it possible to implement a micro thin printed circuit board.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board comprising:
a substrate;
one or more elastic electrode formed on the substrate and made of an elastic material; and
one or more metal electrode formed on the elastic electrode.

2. The printed circuit board as set forth in claim 1, wherein the elastic electrode is made of graphene or graphene oxide.

3. The printed circuit board as set forth in claim 1, wherein the metal electrode is made of a conductive metal.

4. The printed circuit board as set forth in claim 1, further comprising a seed layer formed between the metal electrode and the elastic electrode.

5. The printed circuit board as set forth in claim 1, wherein the metal electrodes are formed on both sides of the elastic electrodes.

6. A method for manufacturing a printed circuit board, the method comprising:
preparing a carrier member having metal layers formed over the entire upper surface thereof;
primarily patterning the metal layers;
forming elastic metal layers on the primarily patterned metal layers and the carrier member;
forming a substrate on the elastic metal layers;
forming elastic electrodes by removing the carrier member; and
forming metal electrodes by secondarily patterning the primarily patterned metal layer.

7. The method as set forth in claim 6, wherein the forming of the primarily patterned metal layers is performed by patterning the metal layers in a form corresponding to the elastic electrodes.

8. The method as set forth in claim 6, wherein in the forming of the metal electrodes,
the secondary patterning is performed on the primarily patterned metal layers so that one or more metal electrodes are formed on the elastic electrodes.

9. The method as set forth in claim 6, wherein in the forming of the metal electrodes,
the secondary patterning is performed on the primarily patterned metal layers so that the metal electrodes are formed on both sides of the elastic electrodes.

10. The method as set forth in claim 6, wherein the metal electrodes are made of a conductive metal.

11. The method as set forth in claim 6, wherein in the forming of the elastic metal layers,
the elastic metal layers are formed by an oxidation and reduction method.

12. The method as set forth in claim 6, wherein the elastic metal layers are made of graphene or graphene oxide.

13. A method for manufacturing a printed circuit board, the method comprising:
preparing a carrier member having metal layers formed over the entire upper surface thereof,
primarily patterning the metal layers;
forming elastic electrodes on the primarily patterned metal layers;
forming a substrate on the elastic electrodes;
removing the carrier member; and
forming metal electrodes by secondarily patterning the primarily patterned metal layers.

14. The method as set forth in claim 13, wherein the forming of the primarily patterned metal layers is performed by patterning the metal layers in a form corresponding to the elastic electrodes.

15. The method as set forth in claim 13, wherein in the forming of the elastic electrodes,
the elastic electrodes are formed by a chemical vapor deposition (CVD).

16. The method as set forth in claim 13, further comprising, after the forming of the primarily patterned metal layers, forming seed layers on the primarily patterned metal layers.

17. The method as set forth in claim 13, wherein in the forming of the metal electrodes,
the secondary patterning is performed on the primarily patterned metal layers so that one or more metal layers are formed on the elastic electrodes.

18. The method as set forth in claim 13, wherein in the forming of the metal electrodes,
the secondary patterning is performed on the primarily patterned metal layers so that the metal electrodes are formed on both sides of the elastic electrodes.

19. The method as set forth in claim 13, wherein the metal electrodes are made of a conductive metal.

20. The method as set forth in claim 13, wherein the elastic metal layer is made of graphene or graphene oxide.
